(19) United States
(12) Patent Application Publication
(10) Pub. No.: US 2015/0168478 A1
(43) Pub. Date: Jun. 18, 2015

(54) METHOD AND APPARATUS FOR MEASURING LOAD TAP CHANGER CHARACTERISTICS

(71) Applicant: Megger Sweden AB, Danderyd (SE)

(72) Inventors: Matz ÖHLEN, Stockholm (SE); Peter WERELIUS, Brottby (SE); Johan UUSIJÄRVI, Bagarmossen (SE)

(21) Appl. No.: 14/633,209

(22) Filed: Feb. 27, 2015

Related U.S. Application Data
(63) Continuation of application No. PCT/SE2013/051008, filed on Aug. 28, 2013.

(30) Foreign Application Priority Data
Aug. 29, 2012 (SE) 1250959-2

(51) Int. Cl. G01R 31/02

(52) U.S. Cl. CPC G01R 31/027

(57) ABSTRACT

A method of measuring the characteristics of a transformer comprises the steps of determining the transformer turns ratio, switching the load tap changer from the current tap position to a subsequent tap position while determining a primary current and measuring the secondary voltage across the secondary side, determining the primary voltage across the primary side, and determining the characteristics of the transformer based on the determined transformer turns ratio, the determined primary current and the measured secondary voltage. Thereby, the static and dynamic characteristics of the transformer including a load tap changer can be determined.

### TECHNICAL FIELD

The present invention relates generally to a method and an apparatus for measuring the characteristics of a transformer provided with a load tap changer.

### BACKGROUND ART

Power system operation and stability is very much dependent on fault free operation of transmission and distribution networks. The transformer is a very important link in connecting these networks of power systems. Failure of these transformers not only equates to loss of time and money but also the power system instability. Even though a majority of transformer failures are attributed to insulation breakdown, the events that trigger this breakdown can be manifold. It could be related to aging, moisture, contamination, operator negligence, failure of transformer accessories and its peripheral components. Load tap changers and bushings are two very important accessories associated with power transformers. Between the two, failures of these accessories contribute to more than 50% of the transformer failures.

Load tap changers (LTC) are used to regulate and maintain a constant voltage under varying load conditions. An LTC operates while the transformer is in service without interrupting the load current. It is achieved by varying the number of regulating winding turns through the change of taps. The LTC being an electrically operated mechanical device requires proper operation of tap selector switch, diverter switch, changeover selector switch, transition resistance/reactance and healthy arcing and main contacts for correct operation. To diagnose the condition of LTC's a detailed testing and maintenance method is required that includes periodic monitoring of contact resistance, make before break operation, degradation of different taps and contacts, quality of insulating oil, turns ratio measurement and transition time from one tap to other.

A general problem is that the voltage across a load tap changer cannot be easily measured because the load tap changer is normally connected in series with a primary winding with high impedance and is physically inaccessible for measuring.

The patent publication EP 2 466 322 A1 discloses a transformer diagnosis apparatus and method which can advantageously be used for on-line diagnosis of a transformer. In one embodiment, the transformer is provided with a comprising a tap changer, wherein the coefficient generator is configured to generate a set of coefficients for each of the tap changer tap points. No measurements are made during the switching of the tap changer.

### SUMMARY OF INVENTION

An object of the present invention is to provide a method of measuring the characteristics of a transformer provided with a load tap changer wherein the drawbacks of prior art methods and apparatuses are eliminated or at least mitigated.

The invention is based on the insight that the inductive voltage of the primary winding of a transformer can be determined by measuring the primary current and the primary and secondary voltages of a transformer during tap changer switching and using knowledge of the transformer turns ratio.

According to a first aspect of the invention, there is provided a method of measuring the characteristics of a transformer comprising a load tap changer and having a primary side with a primary winding having a first number of turns, a secondary side with a secondary winding having a second number of turns, the primary side comprising the load tap changer adapted to be switched between a plurality of tap positions, the method comprising the following steps: a) determining the transformer turns ratio, of the primary and secondary windings, b) switching the load tap changer from the current tap position to a subsequent tap position while determining a primary current through the primary winding and measuring the secondary voltage across the secondary side, c) determining the primary voltage across the primary side, and d) determining the characteristics of the transformer based on the transformer turns ratio determined in step a) and the primary current and the primary and secondary voltages obtained in steps b) and c). In this way, the characteristics of the transformer, including parts which are not accessible from the outside, such as a load tap changer, can be determined.

The step of determining the characteristics of the transformer can be performed either after repeating steps a-c) until a last tap position has been reached or be performed after each run of the steps a)-c) until a last tap position has been reached.

In a preferred embodiment, the step c) comprises determining the primary voltage from parameters of the transformer, including the winding resistance and the characteristics of the test current source, and using this value as an approximate value for the voltage measured during switching and wherein in step c) the characteristics of the load tap changer are determined from the measured primary current, the static primary voltage and the secondary voltage measured during switching in step b).

In a preferred embodiment, the method comprises the additional step after step a) of measuring a primary current on the primary side and a primary voltage across the primary side with the load tap changer in a static position, wherein the load tap changer has essentially zero resistance, and determining the resistance of the primary winding (20) based on the measured primary current and primary voltage.

In a preferred embodiment, the step a) of determining the transformer turns ratio of the transformer is performed by applying an AC voltage component across the primary winding and measuring the resulting voltage across the primary and secondary winding.

In a preferred embodiment, the step a) of determining the transformer turns ratio of the primary and secondary windings is performed by performing calculations based on the transformer nameplate information

In a preferred embodiment, step b) comprises measuring the secondary voltage with a load impedance connected to the secondary winding.

According to a second aspect of the invention, there is provided an apparatus for measuring the characteristics of a transformer comprising a computer program with computer readable code means, which when run causes the apparatus to perform the method according to the invention.

According to a third aspect of the invention, there is provided a computer program product comprising a computer program with computer readable code means, which when run causes an apparatus to perform the method according to the invention.

Further preferred embodiments are defined by the dependent claims.

### BRIEF DESCRIPTION OF DRAWINGS

The invention is now described, by way of example, with reference to the accompanying drawings, in which:

FIG. 1 is a simplified diagram of a transformer with one insertion resistor in series with the primary winding.

FIG. 2 shows a typical diverter switch type load tap changer showing both tap selector switch and diverter switch.

FIG. 3 shows a load tap changer with selector switch.

FIG. 4 is a flow chart showing the different steps comprised in the method according to the invention.

### DESCRIPTION OF EMBODIMENTS

In the following, a detailed description of a method and an apparatus according to the invention will be described.

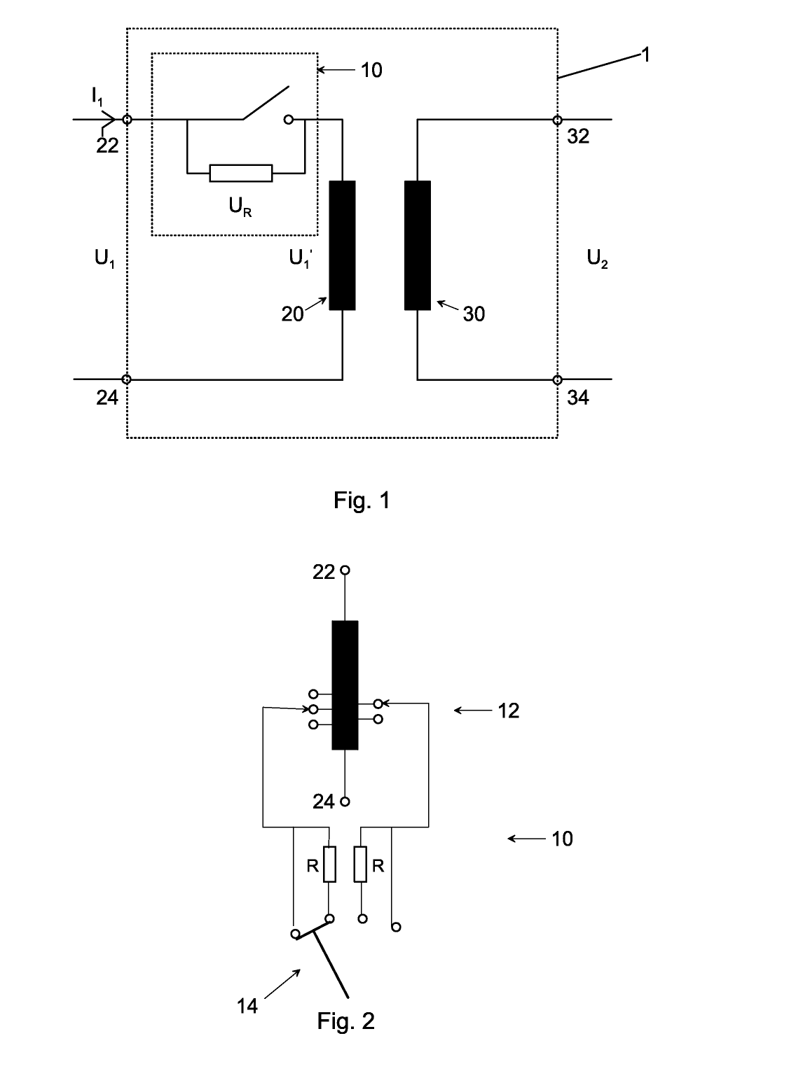

In FIG. 1 a transformer, generally designated 1, is shown. The transformer comprises a primary winding 20 and a secondary winding 30. The primary winding 20 is indirectly accessible through primary side terminals 22, 24 and the secondary winding 30 is accessible through secondary side terminals 32, 34. The transformer is also provided with a load tap changer 10 schematically shown as an insertion resistor connected in series with the primary winding. It will thus be appreciated that the internal of the transformer, including the load tap changer 10 and its connection to the primary winding, is not directly accessible for measuring.

In the following, the voltage across the primary side terminals 22, 24 will be designated U₁ while the voltage across the secondary side terminals 32, 34 will be designated U₂. The voltage across the load tap changer 10 will be designated UR while the internal voltage across the primary winding 20 between the load tap changer 10 and the primary side terminal 24 will be designated U₁′. Thus, it will be appreciated that U₁=U_{R}+U₁′.

The primary winding 20 of the transformer 10 has a first number of turns N₁ while the secondary winding 30 has a second number of turns N₂. Thus, the transformer turns ratio or transformation ratio is defined by the ratio between N₁ and N₂, i.e., N₁:N₂.

FIG. 2 shows a typical diverter switch type load tap changer showing both a tap selector switch 12 and a diverter switch 14. In the present example, the diverter switch 14 is adapted to sequentially interconnect adjacent ones of four terminals, two of which are connected to the tap by means of a resistor R. There is a plurality of tap positions, which can be selected by means of the tap selector switch.

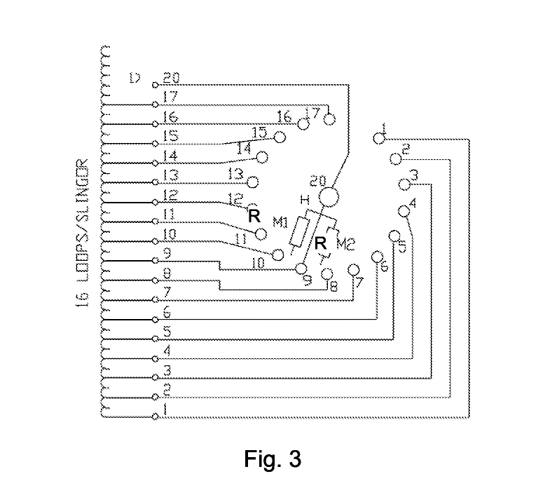

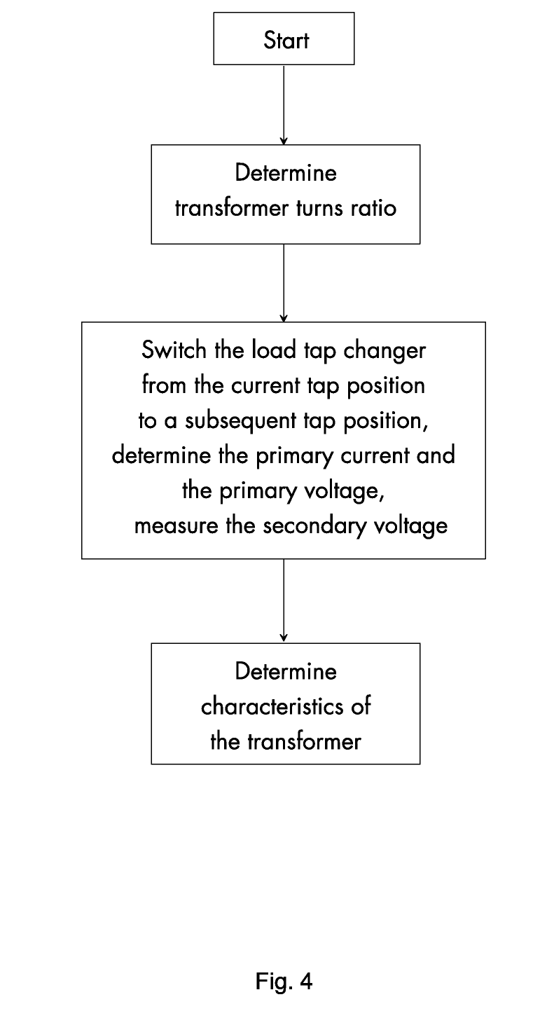

FIG. 3 shows a selector type load tap changer wherein the two operations, i.e., diverting the current and selecting the tap, are performed by a single tap selector switch. Thus, the load tap changer comprises two resistors R which are selectively connected to a plurality of taps, in the present case 17 taps.

The method of measuring the characteristics of diverter resistors of a load tap changer in a transformer will now be explained in detail.

First, the transformer turns ratio of the primary and secondary windings 20, 30 is determined. This can be done in several ways. The most straightforward and simple way is to determine the transformer turns ratio of the transformer by using the nameplate information of the transformer in question. Alternatively, a voltage is applied across the primary winding 20 and the resulting voltage across the secondary winding 30 is measured. It will be appreciated that previously determined values of the transformer turns ratio, i.e., old values can also be used.

After or optionally before the transformer turns ratio has been determined, the load tap changer 10 is switched from the current tap position to a subsequent tap position while determining the primary current I₁ and measuring a secondary voltage U₂ across the secondary side. Also, a primary voltage U₁ across the primary side is measured, Optionally, the primary voltage U₁ can be measured or estimated for a static position of the tap changer and assumed to be constant during the switching of the load tap changer 10. By not measuring the primary voltage during switching, the characteristics of the diverter resistors R may be determined with a somewhat lower accuracy. Thus, the expression “determining” mainly refers to measuring a parameter but previously acquired information can alternatively be used for determining the parameter, such as the primary current and the primary voltage.

The primary current I₁ is preferably determined by connecting a current meter to one of the primary terminals 22, 24. The primary and secondary voltage U₁ and U₂ are preferably measured by connecting a voltage meter across the terminals 22, 24 and 32, 34 on the primary and secondary sides of the transformer 10.

The above mentioned switching of the load tap changer is repeated until a last tap position has been reached and the primary current I₁ the primary voltage U₁ and the secondary voltage U₂ are determined as explained above for each switching. It will be appreciated that the terms “current tap position” and “last tap position” should be interpreted depending on the applied testing procedures. Conventionally, the test procedure involves switching from the first to the last possible taps, which in the case of the load tap changer shown in FIG. 3 means switching from tap 1 to tap 17 via all intermediate taps. However, more limited test procedures are envisaged, involving just the switching from one tap to another tap.

The characteristics of the transformer, and preferably those of the load tap changer 10, are then determined based on the transformer turns ratio N₁:N₂ and the primary current I₁, the primary voltage U₁ and the secondary voltage U₂ which were determined during the above described switching of the load tap changer 10. The characteristics of the load tap changer may include the timing of the load tap changer, the resistance of diverter resistors of the load tap changer, and the contact resistance of the load tap changer. Calculation of switching times and resistor values may be performed directly after switching from one position to the next or after the complete tap changer switching sequence has been completed.

In one embodiment of the method, the primary current I₁ on the primary side and the primary voltage U₁ across the primary side are measured with the load tap changer 10 in its static position, wherein the load tap changer has essentially zero resistance. By this, the resistance of the primary winding 10 can be determined based on the measured primary current and primary voltage. This value, i.e., the resistance of the primary winding, can be used in subsequent calculations.

During switching of the load tap changer, the current I₁ through the primary winding will increase or decrease proportionally to the change of the number of turns. This means that information regarding the momentary change of transformer turns ratio can be derived by measuring the primary current. Thus, in one embodiment, information about the transformer turns ratio of the transformer can be determined by momentarily measuring the primary current I₁.

The above described method of measuring the characteristics of a transformer and particularly those of diverter resistors R of a load tap changer 10 in a transformer involves measuring at least some of the currents and voltages on the primary and secondary sides of the transformer. In one embodiment, the measured current and voltage values are stored for use after the measuring operation. Thus, in this embodiment, the characteristics of the diverter resistors are determined by computer calculations of the switching operation after all switching operations have been completed.

An apparatus for measuring the characteristics of a transformer comprising a load tap changer according to the above described method comprises a test signal generator providing at least but not limited to one variable DC test current providing up to typically 50A or more. Optionally, the test set may contain a test signal generator providing at least but not limited to one variable AC test voltage providing up to typically 100V or more. The apparatus also comprises internal measurement channels for measuring the output test current and voltage and measurement inputs for measuring at least but not limited to one voltage and/or current. Optionally the apparatus may contain circuitry and outputs for controlling tap changer.

The apparatus also comprises circuitry with data processing capability to analyze and process measured voltage and current signals together with the determined transformer turns ratio in order to characterize a transformer with a load tap changer. Alternatively, the data processing capability is provided in a separate unit, such as a personal computer, which in this case is considered to be part of the apparatus.

The apparatus is preferably controlled by means of a computer program with computer readable code means, which when run causes the apparatus to perform the above described method. Thus, a computer program product comprising a computer program is provided.

Preferred embodiments of a method and an apparatus of measuring the characteristics of a load tap changer in a transformer have been described. It will be appreciated that these can be modified without departing from the inventive idea as defined in appended claims. Thus, although it has been described that the load tap changer is provided on the primary side, this primary side can be interpreted as being either the high voltage or low voltage side of a transformer. It will also be appreciated that the load tap changer can be either of the resistive type describe above or alternatively of the reactive type.

The described method is used for determining the characteristics of a transformer and particularly a load tap changer, using knowledge of the transformer turns ratio. It will be appreciated that also other parameters of the transformer may be determined, such as leakage reactance inductance, magnetization inductance etc.

Although only to examples of a load tap changer have been described, it will be appreciated that the claimed method is applicable to any kind of load tap changer.

1. A method of measuring a plurality of characteristics of a transformer comprising a load tap changer and having a primary side with a primary winding having a first number of turns, a secondary side with a secondary winding having a second number of turns, the primary side comprising the load tap changer adapted to be switched between a plurality of tap positions, the method comprising the following steps:
a) determining a transformer turns ratio, of the primary and secondary windings,
b) switching the load tap changer from a current tap position to a subsequent tap position while determining a primary current through the primary winding and measuring a secondary voltage across the secondary side,
c) determining a primary voltage across the primary side, and
d) determining the characteristics of the transformer based on the transformer turns ratio determined in step a) and the primary current and the primary and secondary voltages obtained in steps b) and c).

2. The method according to claim 1, wherein the step d) of determining the characteristics of the transformer is performed after repeating steps a-c) until a last tap position has been reached.

3. The method according to claim 1, wherein the steps a)-d) are repeated until a last tap position has been reached.

4. The method according to claim 1, wherein step c) comprises measuring a value of the primary voltage during switching of the tap changer and using this value as the determined primary voltage and wherein step d) comprises determining the characteristics of the transformer from the determined primary current, the determined primary voltage and the secondary voltage measured during switching in step b).

5. The method according to claim 1, wherein step c) comprises measuring a value of the primary voltage in a static position of the tap changer and using this value as the determined primary voltage and wherein step d) comprises determining the characteristics of the transformer from the determined primary current, the determined primary voltage and the secondary voltage measured during switching in step b).

6. The method according to claim 1 wherein step b) comprises measuring the secondary voltage with the secondary winding connected to a load impedance

7. The method according to claim 1, wherein step c) comprises determining a value of the primary voltage from parameters of the transformer, including a winding resistance and the characteristics of the test current source, and using this value as an approximate value for the primary voltage during switching and wherein in step d) the characteristics of the load tap changer are determined from the measured primary current, static primary voltage and the determined secondary voltage d during switching in step b).

8. The method according to claim 1, comprising the additional step after step a) of measuring a primary current on the primary side and a primary voltage across the primary side with the load tap changer in a static position, wherein the load tap changer has essentially zero resistance, and determining a resistance of the primary winding based on the measured primary current and primary voltage.

9. The method according to claim 1, wherein the step a) of determining the transformer turns ratio of the primary and secondary windings is performed by applying an AC voltage component across the primary winding and measuring the resulting voltage across the secondary winding.

10. The method according to claim 1, wherein the step a) of determining the transformer turns ratio of the primary and secondary windings is performed by means of a calculated value based on transformer nameplate information.

11. The method according to claim 1, wherein the step a) of determining the transformer turns ratio of the primary and secondary windings includes momentarily measuring the primary current.

12. The method according to claim 1, wherein the characteristics of the transformer are determined by computer calculations of a switching operation after all switching operations have been completed.

13. The method according to claim 1, wherein step d) comprises determining the characteristics of the load tap changer, including a timing of the load tap changer, the resistance of diverter resistors of the load tap changer, and the contacts of the load tap changer.

14. An apparatus for measuring the characteristics of a transformer comprising a load tap changer, comprising a computer program with computer readable code means, which when run causes the apparatus to perform the method according to claim 1.

15. A computer program product comprising a computer program with computer readable code means, which when run causes an apparatus to perform the method according to claim 1.
